(19) United States
(12) Patent Application Publication
(10) Pub. No.: US 2020/0083847 A1
(43) Pub. Date: Mar. 12, 2020

(54) SYSTEM AND METHOD FOR BIASING AN AMPLIFIER

(71) Applicant: QUALCOMM INCORPORATED, SAN DIEGO, CA (US)

(72) Inventors: Manohar SEETHARAM, Bangalore (IN); Lai Kan LEUNG, San Diego, CA (US)

(21) Appl. No.: 16/127,588

(22) Filed: Sep. 11, 2018

(51) Int. Cl. H03F 1/30; H03F 3/45; H03G 3/30; H03F 3/195

(52) U.S. Cl. CPC H03F 1/301; H03F 3/45179; H03G 3/30; H03F 3/195; H03F 2203/45374; H03F 2203/45024; H03F 2203/45022; H03F 2200/451; H03F 2200/294; H03F 2200/234

(57) ABSTRACT

A bias circuit includes a differential amplifier including at least two field effect transistors each having a gate, a source and a drain, a gain of the differential amplifier being based at least in part on a gate bias voltage, and a temperature compensation element selectively coupled to the gate of each of the two field effect transistors, the temperature compensation element configured to provide a compensated gate bias voltage across a temperature range.

### FIELD

The present disclosure relates generally to electronics, and more specifically to radio frequency (RF) transmitters and receivers.

### BACKGROUND

Wireless communication devices and technologies are becoming ever more prevalent. Wireless communication devices generally transmit and receive communication signals. A communication signal received by a communication device typically must be amplified to recover the information contained in the communication signal. Typically, a receiver front-end may include one or more of a low noise amplifier (LNA), variable gain amplifier (VGA), one or more filter circuits, and other circuits.

It is generally desirable for an LNA (or other amplifier) to provide linear power amplification over a wide bandwidth. One measure of the linearity of an LNA is referred to as the third order intercept point, referred to as IP3. The IP3 may be characterized by an output IP3 (OIP3) and an input IP3 (IIP3).

Most receive LNAs and VGAs implemented using metal oxide semiconductor (MOS) technology use a common source topology where the 3^{rd} order non-linearity is determined by the non-linearity of the input device gain, or transconductance (Gm), also referred to as gain. The Gm of an amplifier comprising a field effect transistor (FET), and a metal oxide semiconductor FET (MOSFET) in particular, is the change in the drain current divided by the small change in the gate/source voltage (Vgs) with a constant drain/source voltage (Vds). The Gm of the amplifier is subject to non-linearity as a function of the gate bias voltage with a narrowly defined optimum bias voltage. The optimum bias voltage region varies with changes in temperature. For example, over an operating temperature range of approximately −40 C to approximately 125 C, the optimum bias voltage may vary from approximately 330 millivolts (mV) to approximately 440 mV, depending on application. The variation of the optimum bias voltage across temperature worsens the gain variation across temperature due to variation in the gain (Gm) of the amplifier.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a bias circuit including a differential amplifier including at least two field effect transistors each having a gate, a source and a drain, a gain of the differential amplifier being based at least in part on a gate bias voltage, and a temperature compensation element selectively coupled to the gate of each of the two field effect transistors, the temperature compensation element configured to provide a compensated gate bias voltage across a temperature range.

Another aspect of the disclosure provides a method for biasing an amplifier, including generating a temperature compensated bias signal and a non-temperature compensated bias signal, generating a cascode bleed bias signal using the temperature compensated bias signal and the non-temperature compensated bias signal, and reducing a gain variation of an amplifier across a temperature range using the cascode bleed bias signal to adjust a bias current conducted by the amplifier.

Another aspect of the disclosure provides a device including means for generating a temperature compensated bias signal and a non-temperature compensated bias signal, means for generating a cascode bleed bias signal using the temperature compensated bias signal and the non-temperature compensated bias signal, and means for reducing a gain variation of an amplifier across a temperature range using the cascode bleed bias signal to adjust a bias current conducted by the amplifier.

Another aspect of the disclosure provides a bias circuit including a differential amplifier including a first field effect transistor and a second field effect transistor, each field effect transistor having a gate, a source and a drain, a gain of the differential amplifier being based at least in part on a first gate bias voltage applied to the gate of the first field effect transistor and a second gate bias voltage applied to the gate of the second field effect transistor, a temperature compensation element coupled to the gate of the first field effect transistor, a constant current source coupled to the gate of the second field effect transistor, and a resistor coupled between the gate of the first field effect transistor and the gate of the second field effect transistor, a gain of the differential amplifier related to the resistance value of the resistor, wherein the first gate bias voltage comprises a temperature-compensated gate bias voltage generated by the temperature compensation element.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2 is a block diagram showing a wireless device in which the exemplary techniques of the present disclosure may be implemented.

FIG. 3 is a schematic diagram of a bias circuit in accordance with an exemplary embodiment of the disclosure.

FIG. 4 is a schematic diagram of an amplifier circuit configured as an open loop linear amplifier in accordance with an exemplary embodiment of the disclosure.

FIG. 5 is a schematic diagram of a bias compensation circuit that can be used to generate the cascode bleed (casc_bleed) signal and the cascode bias (casc_bias) signal of FIG. 4, in accordance with an exemplary embodiment of the disclosure.

FIG. 6 is a block diagram illustrating the temperature compensation element of FIG. 4 in additional detail.

FIG. 7 is a graphical view showing amplifier gain (Gm) variation across temperature and the effect of temperature compensation on amplifier gain.

FIG. 8 is a flow chart describing an example of the operation of a bias circuit in accordance with an exemplary embodiment of the disclosure.

FIG. 9 is a functional block diagram of an apparatus for a bias circuit in accordance with an exemplary embodiment of the disclosure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

Exemplary embodiments of the disclosure are directed to a bias circuit that can be configured to provide optimum amplifier biasing to provide optimum linearity at the third order intercept point (IP3), or the input IP3 (IIP3), while also compensating for gain variation due to process, supply voltage, and temperature (PVT) variations.

A bias circuit in accordance with exemplary embodiments of the disclosure may be implemented in a low noise amplifier (LNA), a variable gain amplifier (VGA), or other amplifier circuits and may be configured to receive and amplify one or more radio frequency (RF), intermediate frequency (IF), other frequency communication signals from different frequency bands, such as, for example, one or more of LTE, CDMA, 4G, 5G, cellular, Bluetooth, WiFi, etc.

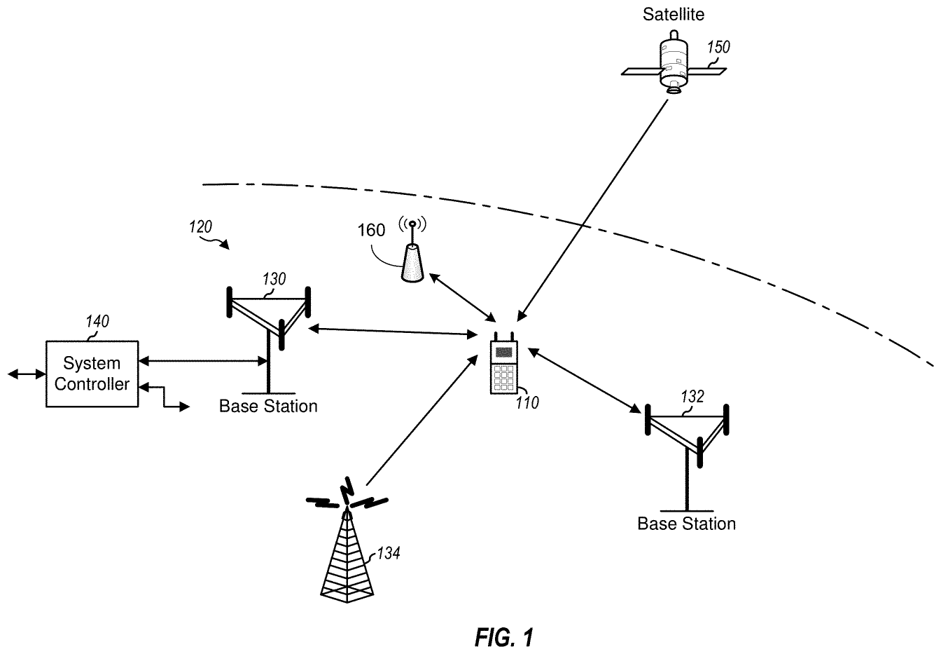

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1×, EVDO, TD-SCDMA, GSM, 802.11, 5G, etc.

Wireless device 110 may support carrier aggregation, which is operation on multiple carriers. Carrier aggregation may also be referred to as multi-carrier operation. In some embodiments, a single stream of data is transmitted using multiple carriers using carrier aggregation, for example as opposed to separate carriers being used for respective data streams.

Wireless device 110 may be able to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz and 3400 to 3800 MHz. Low-band, mid-band, and high-band refer to three groups of bands (or band groups), with each band group including a number of frequency bands (or simply, “bands”). Each band may cover up to 200 MHz and may include one or more carriers. Each carrier may cover up to 20 MHz in LTE. LTE Release 11 supports 35 bands, which are referred to as LTE/UMTS bands and are listed in 3GPP TS 36.101. Wireless device 110 may be configured with up to five carriers in one or two bands in LTE Release 11.

The wireless device 110 may also be in communication with a wireless device 160. In an exemplary embodiment, the wireless device 160 may be a wireless access point, or another wireless communication device that comprises, or comprises part of a wireless local area network (WLAN). An exemplary embodiment of a WLAN signal may include WiFi, or other communication signals that use unlicensed communication spectrum in the range of, for example, 5 GHz to 6 GHz.

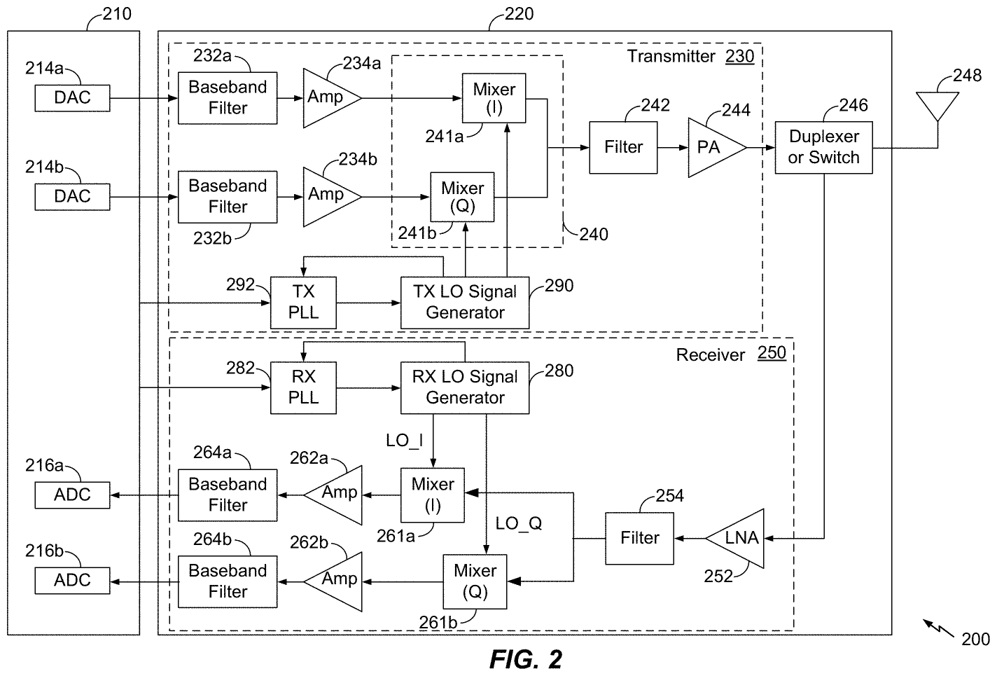

FIG. 2 is a block diagram showing a wireless device 200 in which the exemplary techniques of the present disclosure may be implemented. FIG. 2 shows an example of a transceiver 220. In general, the conditioning of the signals in a transmitter 230 and a receiver 250 may be performed by one or more stages of amplifier, filter, upconverter, downconverter, etc. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, wireless device 200 generally comprises a transceiver 220 and a data processor 210. The data processor 210 may include a memory (not shown) to store data and program codes, and may generally comprise analog and digital processing elements. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband, or near baseband, in one stage. The super-heterodyne and direct-conversion architectures may use different circuit blocks and/or have different requirements. In the example shown in FIG. 2, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion Amplifiers (Amp) 234a and 234b amplify the signals from lowpass filters 232a and 232b, respectively, and provide I and Q baseband signals. An upconverter 240 having an I mixer 241a and a Q mixer 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal is routed through a duplexer or switch 246 and transmitted via an antenna 248.

In the receive path, antenna 248 receives communication signals and provides a received RF signal, which is routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal. Downconversion mixers 261a and 261b mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain elements of the transceiver 220 are functionally illustrated in FIG. 2, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules. For example, the PA 244, the filter 242, and the duplexer 246 may be implemented in separate modules or as discrete components, while the remaining elements illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more bias signals and can be configured in various topologies or architectures.

Exemplary embodiments of the disclosure are directed to a bias circuit that can be used to generate one or more gate bias voltages that optimize IIP3 performance, and that also reduces gain variation, particularly gain variation due to variations in process, supply voltage, and temperature (PVT). Exemplary embodiments of a bias circuit that can be implemented with a low noise amplifier may be implemented within, or as part of, the LNA 252, or other amplifiers within the wireless device 200.

As mentioned above, there is a direct trade-off between linearity performance (or non-linearity performance) and gain variation across process, supply voltage, and temperature variations (PVT) of an amplifier. Receive (RX) chains with many stages can have a very stringent specification on both the linearity and gain variation for its constituent blocks.

A solution to this trade-off between maximizing IIP3 for linearity and gain variation compensation includes adjustability in an amplifier circuit, such as a VGA circuit, to moderate any large gain variation across the temperature range using a current correction element, which, in an exemplary embodiment, may be implemented as cascode current bleed devices having temperature dependent gate bias. A bias generation circuit for a VGA can generate temperature dependent input bias for IIP3 optimization with a predictable Gm variation, which Gm variation can then be compensated for using appropriate biasing at the cascode current bleed devices.

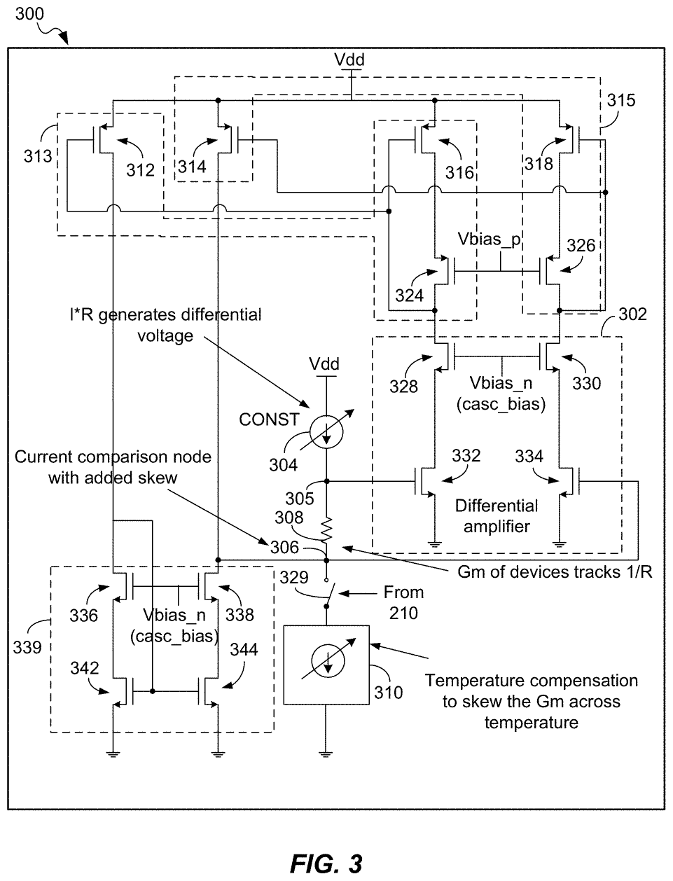

FIG. 3 is a schematic diagram of a bias circuit 300 in accordance with an exemplary embodiment of the disclosure. In an exemplary embodiment, the bias circuit 300 may be used to generate one or more of an optimum IIP3 bias, a constant Gm bias, or another bias signal.

In an exemplary embodiment, the bias circuit 300 comprises transistors 312, 314, 316, 318, 324 and 326, which are shown in FIG. 3 in a pMOS (p-type metal oxide semiconductor) configuration. In an exemplary embodiment, the transistors 312, 316, and 324 form a cascode current mirror 313; and the transistors 314, 318, and 326 form a cascode current mirror 315. In an exemplary embodiment, a bias signal, Vbias_p, is applied to the gates of the transistors 324 and 326. The bias signal, Vbias_p, can be provided by bias circuitry (not shown) as known to those having ordinary skill in the art.

In an exemplary embodiment, the bias circuit 300 also comprises transistors 336, 338, 342 and 344 which form a cascode current mirror 339. In this exemplary embodiment, the transistors 336, 338, 342 and 344 are shown in an nMOS (n-type metal oxide semiconductor) configuration. In an exemplary embodiment, a bias signal, Vbias_n, which is also referred to as a cascode bias signal, casc_bias, described below, is applied to the gates of the transistors 336 and 338. The bias signal, Vbias_n, can be provided by bias circuitry (not shown) using, for example, a replica bias technique as known to those having ordinary skill in the art.

In an exemplary embodiment, the bias circuit 300 also comprises a differential amplifier 302 having transistors 332 and 334, and cascode transistors 328 and 330. In this exemplary embodiment, the transistors 332, 334, 328 and 330 are shown in an nMOS (n-type metal oxide semiconductor) configuration. In an exemplary embodiment, the bias signal, Vbias_n, is applied to the gates of the transistors 328 and 330.

In an exemplary embodiment, the bias circuit 300 also comprises a constant current source 304 coupled to a system voltage, VDD, and coupled to a resistor 308. The gate of the transistor 332 is coupled to one side of the resistor 308 at node 305, and the gate of the transistor 434 is coupled to the other side of the resistor 308 at node 306. The differential amplifier 302 and the constant current source 304 generate a differential voltage across the resistor 308 at node 305 and at node 306.

In an exemplary embodiment, a temperature compensation element 310 is also switchably coupled to the resistor 308 at the node 306. In an exemplary embodiment, the temperature compensation element 310 may include one or more of a proportional to absolute temperature (PTAT) current source, a complementary to absolute temperature (CTAT) current source, or other temperature compensation elements that can be configured to generate a temperature compensated voltage and a temperature compensated current. In an exemplary embodiment, a PTAT current source may generate a temperature-dependent current that has a slope that increases with increasing temperature. In an exemplary embodiment, a CTAT current source may generate a temperature-dependent current that has a slope that decreases with increasing temperature.

In an exemplary embodiment, an output of the bias circuit 300 at the node 306 can be skewed with one or more of a PTAT current slope, and a CTAT current slope developed by the temperature compensation element 310. In an exemplary embodiment, a signal having the PTAT current slope or the CTAT current slope appears at node 306, which is also referred to as a current comparison node. By providing a temperature-compensated current slope at node 306, an optimum gate bias voltage across a temperature range to meet an IP3 (or IIP3) specification can be generated at node 306 and can be used to bias the differential amplifier 302 at an optimum IP3 (or IIP3) gate bias voltage. The gate bias voltage appearing at node 306 may be referred to as a temperature compensated gate bias voltage. In an exemplary embodiment, the bias signal appearing at node 305 will differ slightly from the bias signal applied at node 306 according to the value of the resistor 308. For example, in an exemplary embodiment, the transistor 332 may receive a gate bias voltage of approximately 600 mV and the transistor 334 may receive a gate bias voltage of approximately 605 mV.

However, biasing the differential amplifier 302 using the optimum IP3 (or IIP3) gate bias voltage may give rise to gain variations in the differential amplifier 302. A traditional constant-Gm bias generation circuit is prone to process, supply voltage, temperature (PVT) variations due to circuit and device non-idealities. The bias circuit 300 overcomes these PVT variations by employing temperature-dependent feedback and compensation using the temperature compensation element 310 to adjust the bias voltage and current at the current compensation node 306.

By adding a PTAT current skew or a CTAT current skew at the current comparison node 306 the desired amount of temperature skew can be applied to the Gm of the differential amplifier 302 based at least in part on the varying characteristics of the differential amplifier 302 across its operating temperature. For example, the Gm of the transistors 332 and 334 of the differential amplifier 302 is proportional to 1/R, where R is the value of the resistance 308.

The following exemplary Gm variation was achieved across a temperature range of −40 C to 125 C.
DC Gm: Variation<+/−0.5%→No temp compensation
AC Gm (8.5 GHz): Variation<+/−2.9%→No temperature compensation
   AC Gm (8.5 GHz): Variation<+/−1%→With CTAT (complementary to absolute temperature) temperature compensation.

In an exemplary embodiment, it may be desirable for the bias circuit 300 to provide a bias signal that is not compensated by the temperature compensation element 310. In an exemplary embodiment, a switch 329 may be controlled by a control signal from, for example, the data processor 210, or another controller, to create an instance of the bias circuit 300 that does not provide a temperature-compensated current skew at the current comparison node 306 when the switch 329 is non-conductive, thereby removing the temperature compensation element 310 from the bias circuit 300.

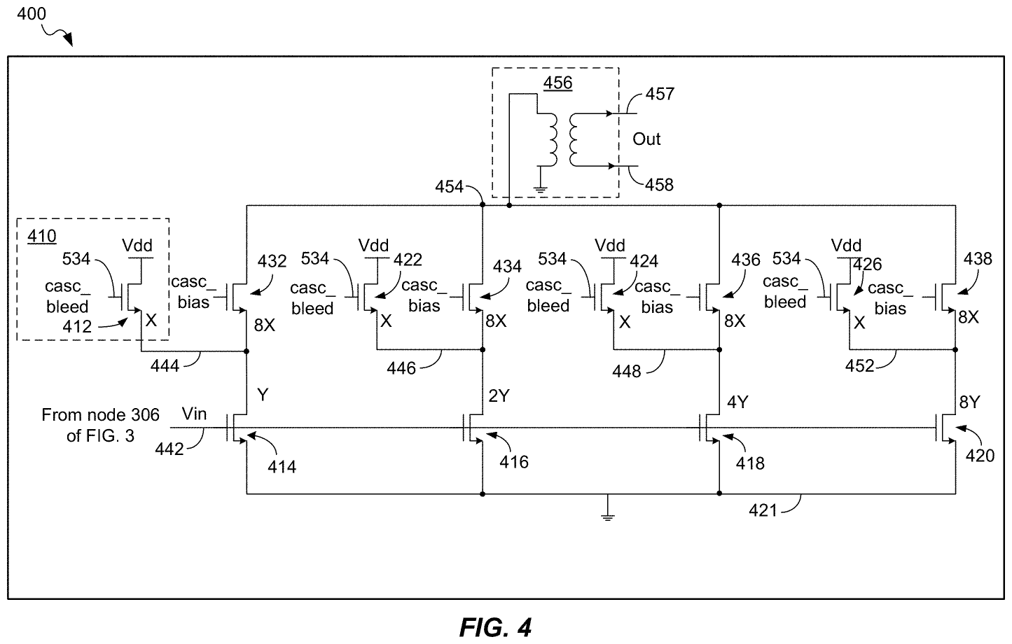

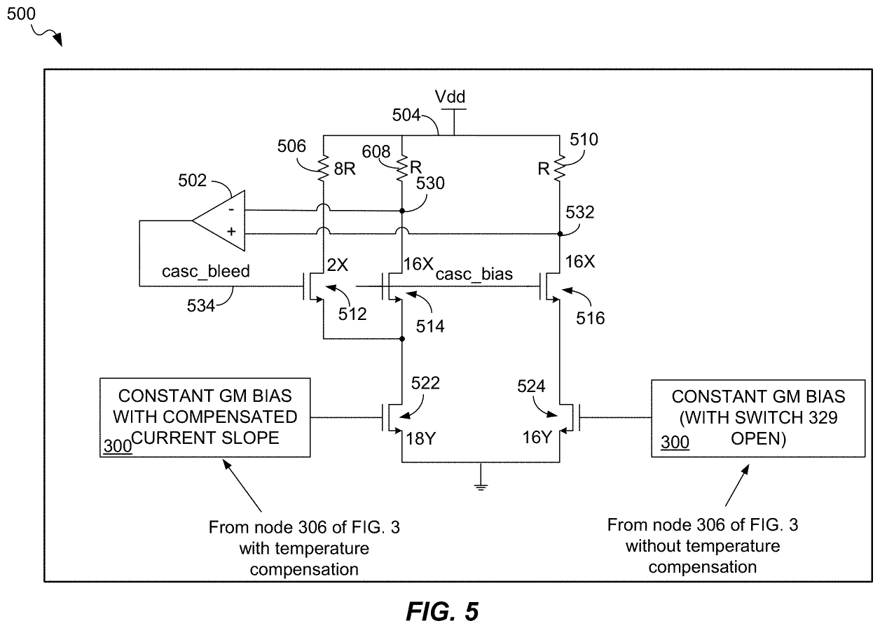

FIG. 4 is a schematic diagram of an amplifier circuit 400 configured as an open loop linear amplifier in accordance with an exemplary embodiment of the disclosure. The amplifier circuit 400 comprises transistors 414, 416, 418 and 420, configured as low voltage amplifiers. The gates of the transistors 414, 416, 418 and 420 are connected together at terminal 442 and are configured to receive the bias signal from the node 306 of FIG. 3. A cascode transistor 432, which may be configured for high voltage operation, is coupled to the transistor 414 in a cascode configuration where the drain of the transistor 414 is coupled to the source of the transistor 432. The transistor 432 receives a cascode bias (casc_bias) signal at its gate. The casc_bias signal can be generated by, for example, a replica bias technique as known to those having ordinary skill in the art. A bleed transistor 412 receives a cascode bleed (casc_bleed) signal (534 from FIG. 5) at its gate, and has its source coupled over connection 444 to the drain of the transistor 414 and the source of the transistor 432.

Similarly, a cascode transistor 434, which may be configured for high voltage operation, is coupled to the transistor 416 in a cascode configuration where the drain of the transistor 416 is coupled to the source of the transistor 434. The transistor 434 receives a cascode bias (casc_bias) signal at its gate. A bleed transistor 422 receives a cascode bleed (casc_bleed) signal (534 from FIG. 5) at its gate, and has its source coupled over connection 446 to the drain of the transistor 416 and the source of the transistor 434.

Similarly, a cascode transistor 436, which may be configured for high voltage operation, is coupled to the transistor 418 in a cascode configuration where the drain of the transistor 418 is coupled to the source of the transistor 436. The transistor 436 receives a cascode bias (casc_bias) signal at its gate. A bleed transistor 424 receives a cascode bleed (casc_bleed) signal (534 from FIG. 5) at its gate, and has its source coupled over connection 448 to the drain of the transistor 418 and the source of the transistor 436.

Similarly, a cascode transistor 438, which may be configured for high voltage operation, is coupled to the transistor 420 in a cascode configuration where the drain of the transistor 420 is coupled to the source of the transistor 438. The transistor 438 receives a cascode bias (casc_bias) signal at its gate. A bleed transistor 426 receives a cascode bleed (casc_bleed) signal (534 from FIG. 5) at its gate, and has its source coupled over connection 452 to the drain of the transistor 420 and the source of the transistor 438.

The cascode bias signal, casc_bias, provided to the gates of the transistors 432, 434, 436 and 438 may be generated by bias circuitry (not shown) to bias the transistors 432, 434, 436 and 438.

In an exemplary embodiment, the transistor 414 may have a size “Y”, the transistor 416 may have a size “2Y”, the transistor 418 may have a size “4Y”, and the transistor 420 may have a size “8Y.” The difference in size of the transistors 414, 416, 418 and 420 allows each of the different size devices to provide a different amount of gain. Further, the transistors 414, 416, 418 and 420 can be selectively combined to provide a wide range of gain, whereby any of the transistors 414, 416, 418 and 420 can be enabled to provide a wide range of gain.

In an exemplary embodiment, the transistors 412, 422, 424 and 426 may have a size “X”, and the transistors 432, 434, 436 and 438 may have a size “8X.”

The amplifier circuit 400 also includes a transformer 456 coupled to node 454 to provide an output from the drain terminals of the transistors 432, 434, 436 and/or 438 on connections 457 and 458. In an exemplary embodiment, the output of the amplifier circuit 400 on connections 457 and 458 may be an RF signal, an IF signal, a baseband signal, or another frequency signal.

In an exemplary embodiment, the transistor 412 operates to provide a current adjustment (bleed) circuit configured to adjust the current flowing through the transistor 432, with an exemplary bleed circuit shown using reference numeral 410. Similarly, the transistors 422, 424 and 426 operate to provide a current adjustment (bleed) circuit configured to adjust the current flowing through the transistors 434, 436, and 438, respectively. In an exemplary embodiment, the transistor 412 may be configured to operate to reduce the current flowing through the transistor 432, and similarly, the transistors 422, 424 and 426 may be configured to operate to reduce the current flowing through the transistors 434, 436, and 438, respectively. For example, if the transistor 414 is conducting a current of, for example, 9 mA, this current is then divided between the transistor 412 and the transistor 432. If the value of the casc_bias signal is equal to the value of the casc_bleed signal, then the transistor 412 will conduct a current of 1 mA and the transistor 432 will conduct a current of 8 mA. If the value of casc_bleed is increased and the value of casc_bias is left the same, the amount of current conducted by transistor 412 will increase and the amount of current conducted by transistor 432 will decrease. This operation may be described as transistor 412 reducing the amount of current conducted by transistor 432.

In an exemplary embodiment, the amplifier circuit 400 uses a bleed transistor 412 to correct for the gain variation that would be otherwise present due to IP3 (or IIP3) optimum gate biasing for the input transistor device 414, by adjusting the current flowing through the transistor 432. A cascode bleed, casc_bleed, bias signal (534 of FIG. 5) biases the transistor 412 to adjust the current flowing through the transistor 432. The casc_bleed bias signal is provided from node 534 of FIG. 5 to be described below. The bias circuit 300 (FIG. 3) provides the bias signal to the input transistor device 414 on connection 442. In an exemplary embodiment, an RF input signal, shown as Vin in FIG. 4, may also be applied to the connection 442.

Cascode bleed transistors 422, 424 and 426 can be similarly biased and can similarly be configured to adjust the current flowing through the transistors 434, 436 and 438, respectively.

Using the cascode bleed transistors 412, 422, 424 and 426 to adjust the current flowing through the transistors 432, 434, 436 and 438, respectively, reduces, compensates, or otherwise corrects for the gain variation across temperature and allows the IP3 (or IIP3) performance of the amplifier circuit 400 to be much closer to the theoretical maximum.

FIG. 5 is a schematic diagram of a bias compensation circuit 500, also referred to as a bleed signal generation circuit, which can be used to generate the cascode bleed (casc_bleed) signal of FIG. 4, in accordance with an exemplary embodiment of the disclosure. The bias compensation circuit 500 includes an operational amplifier 502 configured as a linear amplifier, transistors 512, 514, 516, 522 and 524, resistors 506, 508 and 510, and two exemplary instances of the bias circuit 300 of FIG. 3.

The resistor 506 is coupled to the drain of the transistor 512 and to a system voltage, VDD, on connection 504. Similarly, the resistor 508 is coupled to the drain of the transistor 514 and to a system voltage, VDD, on connection 504; and the resistor 510 is coupled to the drain of the transistor 516 and to a system voltage, VDD, on connection 504. In an exemplary embodiment, the resistor 508 and the resistor 510 may have a value “R” and the resistor 506 may have a value “8R.”

The source of the transistor 512 is coupled to the source of the transistor 514 and the source of the transistor 512 and the source of the transistor 514 are also coupled to the drain of the transistor 522. The source of the transistor 516 is coupled to the drain of the transistor 524. The sources of the transistors 522 and 524 are coupled to a common terminal. The transistors 522 and 524 may be configured as a differential amplifier and the transistors 512 and 514 may be configured as cascode transistors for the transistor 522, and the transistor 516 may be configured as cascode transistor for the transistor 524.

In an exemplary embodiment, the transistor 512 may have a size “X” and the transistors 514 and 516 may have a sixe “nX.” In an exemplary embodiment, the transistor 512 may have a size “2X” and the transistor 514 may have a sixe “16X.” The transistor 516 may also have a size “16X.” The cascode bias signal, casc_bias, provided to the gates of the transistors 514 and 516 may be generated by external bias circuitry (not shown) as described above to bias the transistors 514 and 516.

In an exemplary embodiment, the transistor 522 may have a size “18Y” and the transistor 524 may have a size “16Y.” In an exemplary embodiment, the ratio of the size of the transistor 522 to the size of the transistor 524 (18Y:16Y in this example) will determine the tradeoff between IP3 (or IIP3) performance and gain variation across temperature when used to generate the cascode bleed (casc_bleed) signal on connection 534. In an exemplary embodiment, the transistor 522 and the transistor 524 may be n-type metal oxide semiconductor (nMOS) devices.

In an exemplary embodiment, the ratio between the size of the transistor 522 to the size of the transistors 512 and 514 should be the same as the ratio between the size of the transistor 524 to the size of the transistor 516.

In an exemplary embodiment, the combined sizes of the transistors 512 and 514 relate to the size of the transistor 522 with the same ratio as the size of the transistor 516 relates to the size of the transistor 524.

In an exemplary embodiment, an instance of the bias circuit 300 of FIG. 3 is used to bias the 18Y transistor 522 with a compensated gate bias voltage, that is, the bias circuit 300 of FIG. 3 with the switch 329 closed, or conductive, so that the current comparison node 306 receives a current slope from the temperature compensation element 310 (to track IP3 (or IIP3) optimum bias voltage), and a separate instance of the bias circuit 300 of FIG. 3 is used to bias the 16Y transistor 524 with a non-compensated gate bias voltage, that is, without the temperature compensation element 310 (FIG. 3) to track constant gain bias voltage. In this manner, a current that includes the PTAT and/or CTAT temperature compensation slope from the bias circuit 300 (FIG. 3) appears at node 530, while a current that does not include the temperature compensation slope from an instance of the bias circuit 300 (FIG. 3) without a PTAT or a CTAT current slope appears at node 532. The operational amplifier 502 generates the cascode bleed (casc_bleed) signal on connection 534 that responds to the difference in the current value between the current at node 530 and the current at node 532, thus allowing the cascode bleed (casc_bleed) signal on connection 534 to reflect a temperature-compensated factor to be provided to the cascode bleed (casc_bleed) transistors 412, 422, 424 and 426 of FIG. 4, to adjust the gain variation of the amplifier circuit 400 across temperature and allow IP3 (or IIP3) performance to approach the theoretical maximum.

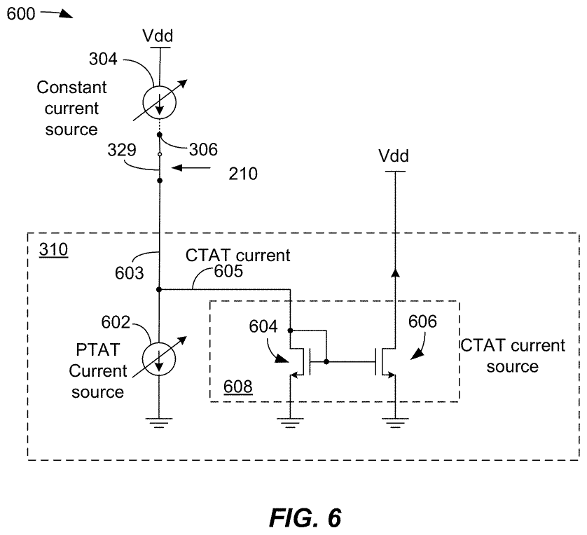

FIG. 6 is a block diagram 600 illustrating the temperature compensation element 310 of FIG. 3 in additional detail. The diagram 600 shows the constant current source 304 of FIG. 3 coupled through the switch 329 to a PTAT current source 602. In an exemplary embodiment, the temperature compensation element 310 also comprises a current mirror 608 having transistors 604 and 606. Once a constant current source 304 and a PTAT current source 602 are available, a CTAT current can be generated by the transistor 606 acting as a CTAT current source by subtracting the PTAT current on connection 603 from the current provided by the constant current source 304, resulting in a CTAT current being available on connection 605. In an exemplary embodiment, the CTAT current on connection 605 can be used to provide the temperature-compensated signal at node 306 of FIG. 3.

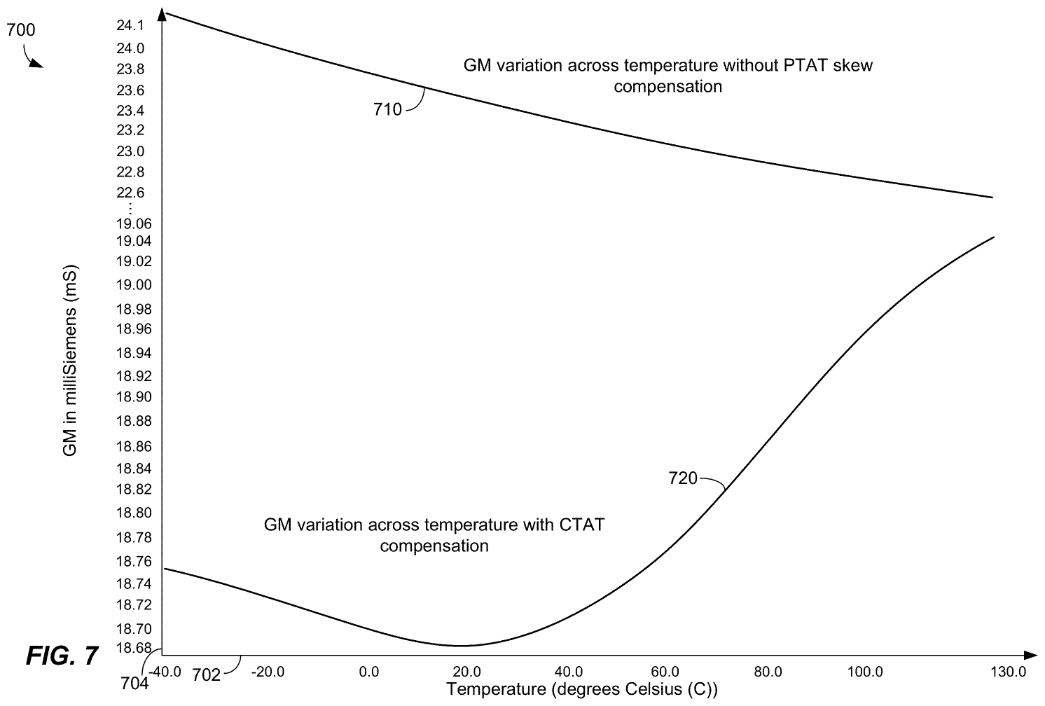

FIG. 7 is a graphical view showing amplifier gain (Gm) variation across temperature and the effect of temperature compensation on amplifier gain. The graph 700 comprises a horizontal axis 702 showing temperature, in degrees Celsius (C), and a vertical axis 704 showing Gm in milliSiemens (mS). The curve 710 illustrates Gm variation across temperature without PTAT or CTAT current skew compensation. The curve 720 illustrates Gm variation across temperature with CTAT current compensation provided by the temperature compensation element 310 (FIG. 3). The scale on the vertical axis 704 is different for the curves 710 and 720 to allow the curves 710 and 720 to be compared on the same figure. As stated above, the curve 710 shows an AC Gm (8.5 GHz) variation of about +/−2.9%, with no temperature compensation, while the curve 720 shows an AC Gm (8.5 GHz) variation of about less than +/−1% with CTAT (complementary to absolute temperature) temperature compensation provided by the temperature compensation element 310 (FIG. 3) providing a CTAT current skew at node 306 (FIG. 3). As shown in FIG. 7, the curve 720 shows an AC Gm variation performance improvement compared to the curve 710.

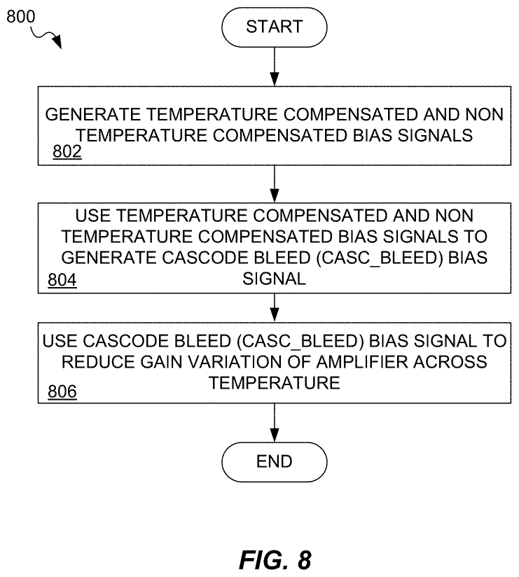

FIG. 8 is a flow chart 800 describing an example of the operation of a bias circuit in accordance with an exemplary embodiment of the disclosure. The blocks in the method 800 can be performed in or out of the order shown, and in some embodiments, can be performed at least in part in parallel.

In block 802, temperature compensated and non-temperature compensated bias signals are generated by the bias circuit 300 (FIG. 3). In an exemplary embodiment, an instance of the bias circuit 300 that includes the temperature compensation element 310 may generate a temperature compensated bias signal, and an instance of the bias circuit 300 that does not include the temperature compensation element 310 may generate a non-temperature compensated bias signal.

In block 804, the temperature compensated and the non-temperature compensated bias signals are used to generate a cascode bleed (casc_bleed) bias signal. In an exemplary embodiment, the bias compensation circuit 500 can be used to generate the cascode bleed (casc_bleed) bias signal.

In block 806, the cascode bleed (casc_bleed) bias signal is used to reduce gain variation of an amplifier across temperature. In an exemplary embodiment, the cascode bleed (casc_bleed) bias signal can be applied to the cascode bleed (casc_bleed) transistors of the amplifier circuit 400 to reduce gain variation of the amplifier across temperature.

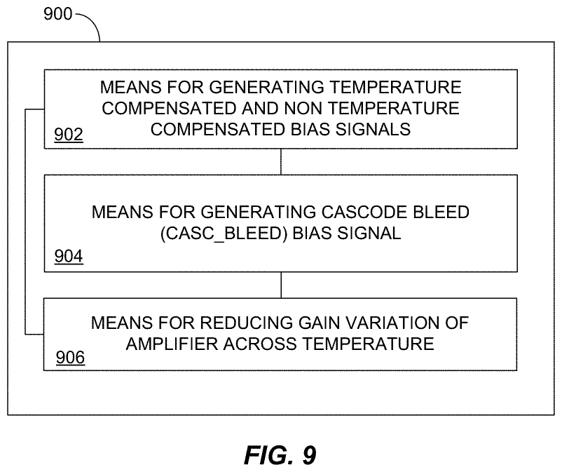

FIG. 9 is a functional block diagram of an apparatus for a bias circuit in accordance with an exemplary embodiment of the disclosure.

The apparatus 900 comprises means 902 for generating temperature compensated and non-temperature compensated bias signals. In certain embodiments, the means 902 for generating temperature compensated and non-temperature compensated bias signals can be configured to perform one or more of the functions described in operation block 802 of method 800 (FIG. 8). In an exemplary embodiment, the means 902 for generating temperature compensated and non-temperature compensated bias signals may comprise an instance of the bias circuit 300 (FIG. 3) that includes the temperature compensation element 310 generating a temperature compensated bias signal (that is, switch 329 being conductive), and an instance of the bias circuit 300 that does not include the temperature compensation element 310 generating a non-temperature compensated bias signal (that is, switch 329 being non-conductive).

The apparatus 900 also comprises means 904 for generating a cascode bleed (casc_bleed) bias signal. In certain embodiments, the means 904 for generating a cascode bleed (casc_bleed) bias signal can be configured to perform one or more of the functions described in operation block 804 of method 800 (FIG. 8). In an exemplary embodiment, the means 904 for generating a cascode bleed (casc_bleed) bias signal may comprise the bias compensation circuit 500 (FIG. 5) generating the cascode bleed (casc_bleed) bias signal.

The apparatus 900 also comprises means 906 for reducing gain variation of an amplifier across temperature. In certain embodiments, the means 906 for reducing gain variation of an amplifier across temperature can be configured to perform one or more of the functions described in operation block 806 of method 800 (FIG. 8). In an exemplary embodiment, the means 906 for reducing gain variation of an amplifier across temperature may comprise the cascode bleed (casc_bleed) bias signal being applied to the cascode bleed (casc_bleed) transistors of the amplifier circuit 400 (FIG. 4) to reduce gain variation of the amplifier across temperature.

The bias circuit architecture described herein described herein may be implemented on one or more ICs, analog ICs, RFICs, mixed-signal ICs, ASICs, printed circuit boards (PCBs), electronic devices, etc. The bias circuit described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the bias circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in various hardware. Although selected aspects have been illustrated and described in detail, it will be understood that various substitutions and alterations may be made therein without departing from the spirit and scope of the present invention, as defined by the following claims.

What is claimed is:

1. A bias circuit, comprising:
a differential amplifier including at least two field effect transistors each having a gate, a source and a drain, a gain of the differential amplifier being based at least in part on a gate bias voltage; and
a temperature compensation element selectively coupled to the gate of each of the two field effect transistors, the temperature compensation element configured to provide a compensated gate bias voltage across a temperature range.

2. The bias circuit of claim 1, wherein the bias circuit is implemented in a variable gain amplifier (VGA), the VGA having a current bleed device configured to adjust a gain of the VGA responsive to gain variation resulting from at least one of temperature and process variation.

3. The bias circuit of claim 2, further comprising a bias compensation circuit configured to provide a bleed bias signal to the current bleed device of the VGA, the bleed bias signal responsive to the residual gain variation of the differential amplifier across the temperature range.

4. The bias circuit of claim 1, wherein the temperature compensation element comprises at least one of a proportional to absolute temperature (PTAT) current source and a complementary to absolute temperature (CTAT) current source.

5. The bias circuit of claim 3, wherein the bias compensation circuit comprises:
a differential amplifier having a first bias compensation transistor configured to receive the compensated gate bias voltage and a second bias compensation transistor configured to receive a non-compensated gate bias voltage; and
an operational amplifier configured to compare a current through the first bias compensation transistor and a current through the second bias compensation transistor and develop the bleed bias signal based on a difference between the current through the first bias compensation transistor and the current through the second bias compensation transistor.

6. The bias circuit of claim 5, wherein the current through the first bias compensation transistor is responsive to the compensated gate bias voltage and the current through the second bias compensation transistor is responsive to the non-compensated gate bias voltage.

7. The bias circuit of claim 2, wherein the VGA further comprises a cascode transistor and an input transistor, a source of the current bleed device coupled to a source of the cascode transistor and a drain of the input transistor.

8. The bias circuit of claim 5, wherein two instances of the bias circuit generate the compensated gate bias voltage and the non-compensated gate bias voltage.

9. The bias circuit of claim 6, wherein the first bias compensation transistor and the second bias compensation transistor have different sizes.

10. The bias circuit of claim 6, further comprising:
a first cascode bias compensation transistor coupled to the first bias compensation transistor; and
an additional cascode bias compensation transistor coupled to the operational amplifier and to the first cascode bias compensation transistor.

11. The bias circuit of claim 10, further comprising a second cascode bias compensation transistor coupled to the second bias compensation transistor, wherein the combined size of the first cascode bias compensation transistor and the additional cascode bias compensation transistor is equal to the size of the second cascode bias compensation transistor.

12. The bias circuit of claim 11, wherein the combined sizes of the first cascode bias compensation transistor and the additional cascode bias compensation transistor relate to the size of the first bias compensation transistor with the same ratio as the size of the second cascode bias compensation transistor relates to the size of the second bias compensation transistor.

13. A method for biasing an amplifier, comprising:
generating a temperature compensated bias signal and a non-temperature compensated bias signal;
generating a cascode bleed bias signal using the temperature compensated bias signal and the non-temperature compensated bias signal; and
reducing a gain variation of an amplifier across a temperature range using the cascode bleed bias signal to adjust a bias current conducted by the amplifier.

14. The method of claim 13, wherein the temperature compensated bias signal is generated using at least one of a proportional to absolute temperature (PTAT) current slope and a complementary to absolute temperature (CTAT) current slope.

15. The method of claim 13, wherein the cascode bleed bias signal is generated by measuring a difference in current flowing through a first transistor biased by the compensated gate bias voltage and a second transistor biased by the non-compensated gate bias voltage.

16. The method of claim 13, wherein using the cascode bleed bias signal to adjust current through the amplifier comprises reducing an amount of current flowing through the amplifier.

17. A device, comprising:
means for generating a temperature compensated bias signal and a non-temperature compensated bias signal;
means for generating a cascode bleed bias signal using the temperature compensated bias signal and the non-temperature compensated bias signal; and
means for reducing a gain variation of an amplifier across a temperature range using the cascode bleed bias signal to adjust a bias current conducted by the amplifier.

18. The device of claim 17, wherein the temperature compensated bias signal is generated using at least one of a proportional to absolute temperature (PTAT) current slope and a complementary to absolute temperature (CTAT) current slope.

19. The device of claim 17, wherein the cascode bleed bias signal is generated by measuring a difference in current flowing through a first bias compensation transistor biased by the compensated gate bias voltage and a second bias compensation transistor biased by the non-compensated gate bias voltage.

20. The device of claim 17, wherein using the cascode bleed bias signal to adjust current through the amplifier comprises reducing an amount of current flowing through the amplifier.

21. A bias circuit, comprising:
a differential amplifier including a first field effect transistor and a second field effect transistor, each field effect transistor having a gate, a source and a drain, a gain of the differential amplifier being based at least in part on a first gate bias voltage applied to the gate of the first field effect transistor and a second gate bias voltage applied to the gate of the second field effect transistor;
a temperature compensation element coupled to the gate of the first field effect transistor;
a constant current source coupled to the gate of the second field effect transistor; and
a resistor coupled between the gate of the first field effect transistor and the gate of the second field effect transistor, a gain of the differential amplifier related to the resistance value of the resistor, wherein the first gate bias voltage comprises a temperature-compensated gate bias voltage generated by the temperature compensation element.

22. The bias circuit of claim 21, wherein the temperature compensation element is configured to correct for residual gain variation of the differential amplifier across the temperature range.

23. The bias circuit of claim 21, wherein the bias circuit is implemented in a variable gain amplifier (VGA), the VGA having a current bleed device configured to adjust a gain of the VGA responsive to gain variation resulting from at least one of temperature and process variation.

24. The bias circuit of claim 21, wherein the temperature compensation element comprises at least one of a proportional to absolute temperature (PTAT) current source and a complementary to absolute temperature (PTAT) current source.

25. The bias circuit of claim 23, further comprising a bias compensation circuit configured to provide a bleed bias signal to the current bleed device of the VGA, the bleed bias signal responsive to the residual gain variation of the differential amplifier across the temperature range.

26. The bias circuit of claim 25, wherein the bias compensation circuit comprises:
a differential amplifier having a first bias compensation transistor configured to receive the compensated gate bias voltage and a second bias compensation transistor configured to receive a non-compensated gate bias voltage; and
an operational amplifier configured to compare a current through the first bias compensation transistor and a current through the second bias compensation transistor and develop the bleed bias signal.

27. The bias circuit of claim 26, wherein the current through the first bias compensation transistor is responsive to the compensated gate bias voltage and the current through the second bias compensation transistor is responsive to the non-compensated gate bias voltage.
